(19) United States
(12) Patent Application Publication
(10) Pub. No.: US 2005/0243655 A1
(43) Pub. Date: Nov. 3, 2005

(54) Programmable analog display timer system

(76) Inventors: Shawn McCutcheon, White Bear Lake, MN (US); Stewart M. James, White Bear Lake, MN (US)

Correspondence Address: FISH & RICHARDSON P.C., PO BOX 1022, MINNEAPOLIS, MN, 55440-1022, US

(21) Appl. No.: 11/109,472

(22) Filed: Apr. 19, 2005

Related U.S. Application Data
(60) Provisional application No. 60/563,504, filed on Apr. 19, 2004.

(51) Int. Cl. G04F 8/00; G04F 10/00; H03M 1/06

(52) U.S. Cl. 368/107

(57) ABSTRACT

A Programmable Analog Display Timer System (PAT) can include an analog indication of time according to one or more programmable time bases. In certain embodiments, the PAT can be programmed to operate one or more analog indicators at independent time bases. During operation, each of the analog indicators can advance at a rate determined by the programmed time base. Upon viewing the analog display, an observer may quickly ascertain proportional, relative, and remaining time information from the position or angle of each indicator.

### CROSS-REFERENCE TO RELATED APPLICATION

The present application claims the benefit of the filing date of U.S. Provisional Application No. 60/563,504, which was filed on Apr. 19, 2004 by McCutcheon et al. and entitled “Programmable Variable-Speed Single- or Multi-Revolution or Linear Analog Display Timer System and Illustrative Chess Clock.” The contents of U.S. Provisional Application No. 60/563,504 are incorporated herein by reference.

### TECHNICAL FIELD

This invention relates to timing devices, and in particular embodiments, to timing devices that have programmable time bases.

### BACKGROUND

Timing devices (timers) serve as tools to display information about the advance of time. Some timing devices, such as an hourglass or a cooking timer, may operate for a fixed amount of time and typically advance at a fixed rate.

Typical timing devices are calibrated to display their advance in intervals corresponding to the standard time of seconds, minutes, and hours. Such timers are designed to advance at a fixed rate, and to display their advance at this rate.

Modern timers may display time using analog indicators or numeric indicators. An analog indicator is non-numeric and may be implemented by a mechanical hand or a sweeping image on a graphic display such as an expanding or shrinking pie or bar graph. A numeric indicator features numbers, produced for example by an LCD. One familiar analog indicator is the hand of a clock. An analog clock is typically designed to rotate a second hand, a minute hand, and an hour hand about an axis at respective rates to make one revolution each standard minute, hour, or 12 standard hours, respectively. In contrast, a numeric clock may display numbers in a format such as hour:minute:second. Like clocks, many other timing devices are generally designed to display time as advancing at a single, predetermined rate.

### SUMMARY

A Programmable Analog-display Timer system (PAT) can include an analog indication of time according to one or more programmable time bases. In certain embodiments, the PAT can be programmed to operate one or more analog indicators at independent time bases. During operation, each of the analog indicators can advance at a rate determined by the programmed time base. Upon viewing the analog display, an observer may quickly ascertain proportional, relative, elapsed and remaining time information from the position or angle of each indicator.

In various embodiments, the indicators may include a marker that rotates at the programmed rate around an axis and through a predetermined angle. Other PATs may advance a marker along a non-circular path at the programmed rate. In some examples, the time base may be linear or non-linear (e.g., discontinuous, logarithmic), and may be programmed to have multiple modes of operation. One or more users may program independent time bases, and the display may include various indicia of time.

In one particular embodiment, the PAT may be used as a chess timer with an appearance that may resemble a conventional chess clock. It may house dual analog time display indicators that display the elapsed time for each corresponding player. In one exemplary mode of operation, two opposing activation buttons may switch between displays (i.e., activating player A's timer stops player B's timer, and vice versa). It may feature other displays and additional controls. For example, the timers may be configured to operate according to various modes of game play familiar to some chess players. In this particular embodiment, the total time available to a player may be indicated by a single, 360° sweep of the analog hand around the clock face. Accordingly, each player's hand may start from the 12 o'clock position, regardless of the set total time (TT). This may be the case even where players are given different TT's, (e.g., 5 minutes and 2 minutes) to allow players of unequal skill levels to compete against each other on terms that are more equal. In certain embodiments, the timers can be programmed for other start/end positions, or for multiple sweeps if so desired by the players.

Some embodiments may provide one or more advantages. For example, multiple analog readouts that advance at variable rates may promote rapid and intuitive comparative measurements at a glance, especially when the indicator travel range is known. For instance, competing players may be able to rapidly compare two single-revolution analog indicators. In a single revolution embodiment, a full 360° sweep yields more precise relative time information than that provided by, for example, a conventional 30° movement for a five-minute chess game. Some embodiments may also permit an instantaneous comparison of one player's proportional remaining time in relation to the other's. Furthermore, the independently programmable sweep rates may permit, for example, players of different skill levels to compete at comparable degrees of difficulty, much as a handicap in other competitive matches can equalize the challenges for players of different skill levels. In some examples, the rate can also be varied to adjust the level of difficulty for an individual user. In certain non-competitive applications, the programmable sweep rate may allow any user to intuitively determine, at a glance, the proportion of time remaining relative to the programmed total time.

The details of one or more embodiments of the invention are set forth in the description below and in the accompanying drawings. Other features, objects, and advantages of the invention will be apparent from the description and drawings, and from the claims.

### DESCRIPTION OF DRAWINGS

FIGS. 1A and 1B are respectively front and back perspective views of a two-player embodiment of a timing system.

FIG. 2A is a perspective view of a four-player embodiment of a timing system.

FIG. 2B is cross section view of a multi-player timing system.

FIG. 3 is a block diagram of a timing system.

FIG. 4 is a system block diagram.

FIGS. 5 and 6 are circuit schematics illustrating certain blocks of FIG. 4.

FIG. 7 is a flowchart of a method of programming a timing system.

FIG. 8 is a flowchart of a method of operating a timing system.

Like reference symbols in the various drawings indicate like elements.

### DETAILED DESCRIPTION OF ILLUSTRATIVE EMBODIMENTS

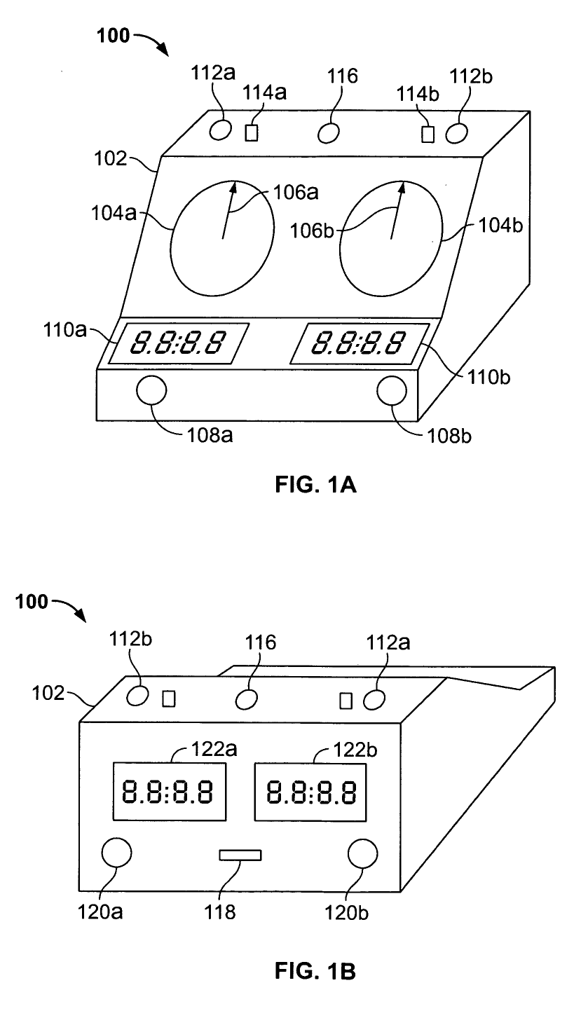

In FIG. 1A, a timing system 100 includes an enclosure 102. On the front panel of the enclosure 102 are two analog displays 104a, 104b, each with a hand (or indicator) 106a, 106b, rotary selectors 108a, 108b, and digital readout displays 110a, 110b. As such, the front panel incorporates both analog and numeric readouts for each player.

According to certain embodiments and modes of operation, each player's clock 106 advances only during his/her turn. As the analog clock 106 advances, the corresponding numeric readout display 110 is decremented. Both analog displays 106 may move one full revolution during play, but over the course of the programmed times that may be unequal. For example, an advanced player may have 5 minutes playtime while a competing novice may have 15 minutes playtime. Both users' analog displays 106 sweep a single revolution over their respective playtimes, but at independently programmable rotational rates.

The analog readout 104 may be a single revolution indicator that is set to revolve at a linear rate, one revolution over the programmed time interval. There are many possible alternatives, including multiple revolutions and non-linear or variable rate modes. Normally, the system 100 will start and end games with the analog hands at the 12 o'clock (vertical) position. The hands may have a positional resolution of 0.1 degree, or 3600 steps per complete revolution (360 degrees). In other examples, any practical number of steps may be used for any practical angle of rotation.

The numeric readout displays 110 on the front panel may display each player's remaining time in minutes and seconds. Alternate time formats are also possible, including hours and minutes, seconds and tenths or hundredths of a second. The numeric readout is especially useful for programming the amount of playtime for each player. In addition, the numeric display may be used for other purposes, like displaying the number of moves made by each player, or, when communicated with a game board equipped with sensors, displaying a record of each player's moves, e.g., in alpha-numeric code. A combination numeric display is also possible, showing the number of moves and the time remaining.

Three switches on the top of the system may be used for player timing and mode selection, including the left and right switches 112a, 112b, and an operate switch (or button) 116 in the center. These switches may be momentary switches, touch switches, buttons, dials, or other input mechanism.

Two indicators 114a, 114b, which may be LEDs, are also mounted on top of the enclosure 102 to indicate which player is active. In some embodiments, only the active player's hand 106 is advancing. Two rotary selectors 108a, 108b are located on the front, and two rotary selectors 120a, 120b are optionally located on the rear panel. These selectors are primarily used to program the player time, but may be used also for analog clock calibration and for game setup. These rotary selectors (which may be implemented as rotary encoders) provide intuitive play setup.

In FIG. 1B, the rear panel of the system may shows another (optional) numeric display for play or setup. The rear panel system may also be used as a stand-alone dual numeric clock timer without the analog indicators. A port 118 is optionally included to provide for communication with other devices. The port 118, as will be described in more detail below, may include wired or wireless communication capability. In one embodiment, the timing system 100 may send information for display via a computing system (e.g., a desktop computer) over a serial connection. In another embodiment, the port 118 is configured to receive programming and control instructions via an infrared link.

For purposes of understanding, exemplary operation of an illustrative embodiment is now described. To initiate operation, a user may first turn on the system by pressing the button 116. The displays 110, 122 may then turn on when the unit turns on. If the batteries are functional, a sound may also be presented from the optional speaker. Two front panel numeric readouts 110 display a default value for the playtime, for example “5:00,” indicating each player has 5 minutes of playtime. None of the LEDs 114 will be on, as the game has not been started. The user may adjust the player minutes, as desired, using the rotary selectors 108 or 120 on either the front or rear panels, respectively. Each player's game time will display on the numeric readouts 110, 122.

The analog clock hand may be calibrated as needed to position the hands 106 at the desired location on the analog displays 104. To reposition the clock hand 106, the user may press and hold the button 116 and the appropriate player's switch 112, and then turns the player's rotary selector 108 or 120 until the hand is in the desired position. Rotating the selectors 108 or 120 one way advances the hand clockwise, and rotating them the other way the hand counter-clockwise (referred to herein as retreating). When the hands 106 are in their correct positions, both buttons 112 are released. This procedure may be referred to as “calibration,” and may be required on one or both analog clocks, depending on use.

To start the game, according to one example, a first player presses his or her play switch 112. This starts the opponent's clock running and turns on the opponent's active LED 114. The opponent presses his play button 112 when the move is complete, which stops his clock 106, turns off their LED 114, and starts the first player's clock 106 and activates his LED 114. Play may go back and forth as players press their play switches 112. If both players agree to pause the game, they may press the center operate button 116 to pause, then again to resume the game. Once one player's time expires, all timing stops, and the loser's LED remains lit or blinks, for example. The analog readout, or hand 106, will typically be at the 12:00 position on the display 104, and the numeric display 110 may read 0:00 remaining time. To turn the system 100 OFF, the user can hold the operate button 116 down for at least two seconds. The displays 110, 122 will turn off when the unit 100 turns off.

In one exemplary embodiment, a user may be able to program the system 100 to provide timing functions for playing chess according to various rules familiar to some chess players. In one exemplary chess play mode, the system may be programmed to permit programmable extra time, either as “free time” for each player before time counts off a player's clock (delayed operation), or as additional time added per move. In other embodiments, the following chess modes of play may be supported by a PAT: five-minute, blitz, andante, adagio, byo-yomi (Japanese, andante, progressive, Canadian, etc.), Go, Ing, hour-glass, progressive, count down, count up, sudden death, delay and move counter, shogi, shuffle chess, FIDE modes. Other modes may be supported as well.

In various embodiments, a timing system 100 may be operated by using one or more controls. For example, a timing system may include controls that enable a user to configure a mute function to disable the signal that may be produced to announce an optional winner sound or a loser sound (bell, beep, music, etc.), as triggered by the expiration of a player's time. The mute winner/loser LEDs (flashing or steady) triggered by the expiration of a player's time. The user interface may also permit the user to control the sweep rate to be, for example, linear progression, non linear (logarithmic, arithmetic, etc.) progression, and last N minutes for a separate full rotation. User interface controls may also be configured to enter a number for programmable number of revolutions per TT.

On PATs that include numerical displays, time may be displayed in a variety of formats, such as HH:MM, MM:SS or SS:hundredths. Optionally, the display format may be programmed to change during the game, for example, by increasing the displayed time resolution when one hour, or one minute, remains.

Remote functions may be incorporated into the system using wired communication links, such as USB, Ethernet, RS-232, RS-485, parallel, serial, or similar interface. Communication may also be over wireless links, using infrared, RF, or optical interfaces. The communication links may be, for example, between the PAT 100 and a computer. In another example, the communication may be between the system 100 and a handheld display device, such as a PDA (portable digital assistant).

Communication with remote devices, whether over wired or wireless links, may enable remote control or remote display. Accordingly, the PAT may be remotely programmed or remotely operated (e.g. switches detached from clock). In addition, the PAT may send information to a remote display.

In one example, the PAT may be set-up via PDA or other wireless user interface. Remote numeric and/or analog displays may provide enlarged or enhanced displays of information. Such information may include, for example, elapsed and relative time, the number of moves made, and statistical information. The information may be displayed on monitors, projection screens, or other vehicles and formats. The communication link may include security protocols to prevent unauthorized remote control. In addition, input controls, switches, displays, and function controls may be operated by other wired or wireless means. For example, time information, including end of match, may be communicated to a tournament director or monitored via remote means. The device may page a player who has left the board when it is his or her move. In one example, commands and information sent and received by the PAT travel in part over the Internet.

Additional displays may be associated with various embodiments. For example, additional rotary or linear displays may be integrated (either within the clock or positioned remotely) to interpret the difference of pace or progress between players (adjusted for the different TT awarded each player), or to indicate a change in pace for each player. The remote displays may also display, for example, a predetermined ideal rate of play for comparison with the actual pace of play.

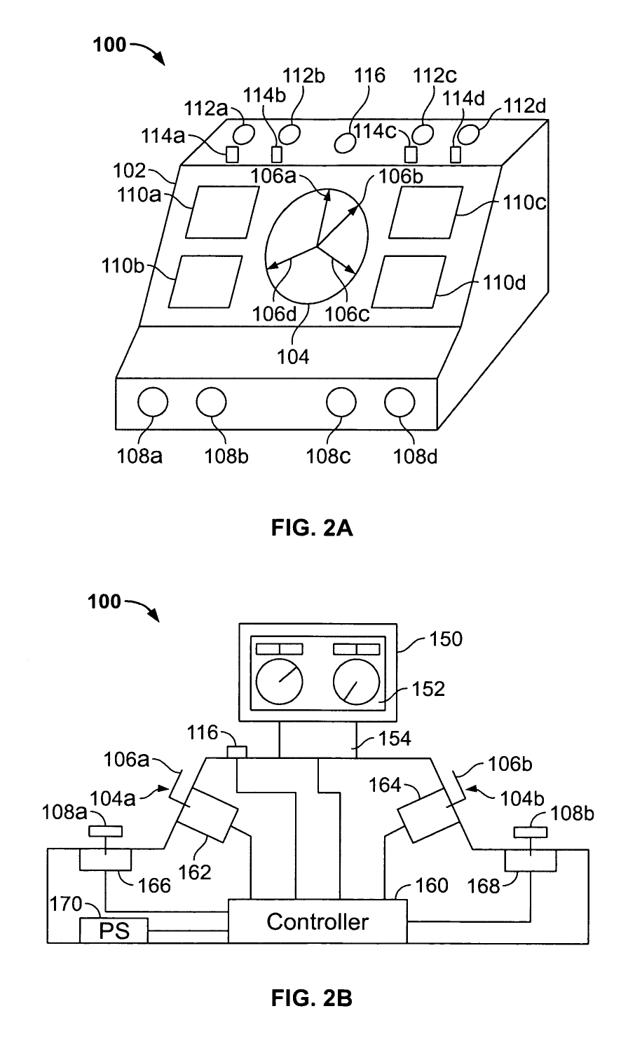

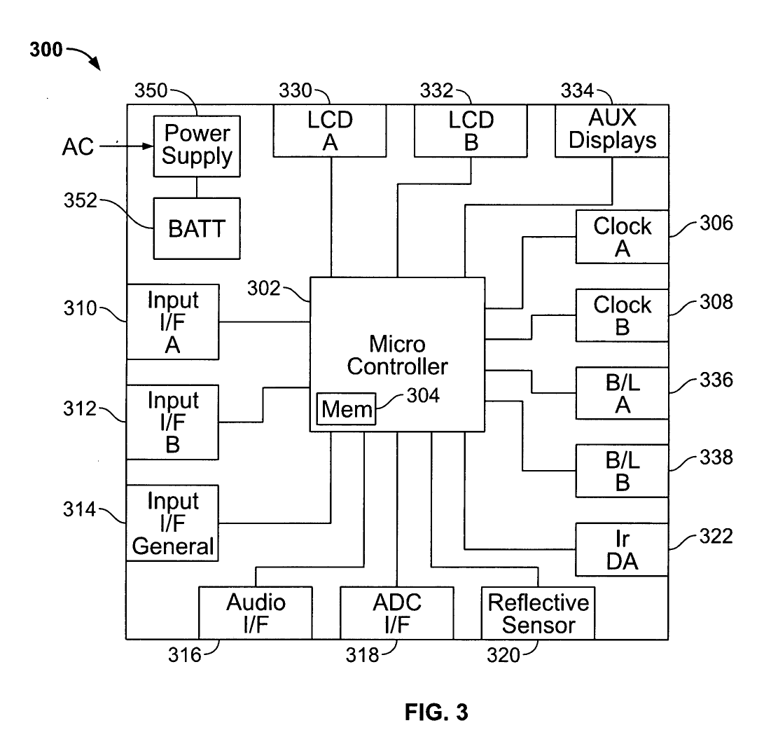

In another embodiment, two or more hands may be incorporated into a single display. As an alternative to having separate displays for each player/participant, as shown in FIG. 1A, an embodiment may have multiple hands within a single display 104, as shown in FIG. 2A. In that embodiment, each hand 106a-106d may represent the time associated with a different player or participant.

Another embodiment that is capable of supporting multiple revolution modes includes two coordinated hands for each player. For example, two hands may represent the conventional minute and hour hands of a clock. Alternatively, one hand indicates the number of revolutions remaining, while the other hand indicates the remaining portion of the current revolution.

As shown in FIGS. 1A, 1B, and 2A, the system may include LCD readouts on the front panel, such as displays 110 and/or 104, or the rear panel, such as displays 122. Other displays may optionally be located remotely via wired or wireless (e.g., RF, infrared, optical, and the like) means. Displays may be implemented using any suitable technology, some examples of which may include: LCD, LED, plasma, or electroluminescent.

One example of an auxiliary display 150 is shown in FIG. 2B. The display 150 includes a display screen 152 that may provide, for example, a graphical representation of the analog display elements 106. The display 150 may be pivoted around a support base 154 that is coupled to controller 160, for example, by a wiring harness. In this example, the controller 160 may send display information to the display 150 that is subsequently displayed on a matrix of pixels on the display screen 152. Using such a graphical display permits the use of special effects to enhance the display. For example, the display screen 152 may display a representation of the analog display elements including animation, 3-D effects, and special effects such as flashing, color, and other similar effects. In addition, other information may be used to augment the analog display representation. For example, the programmed rate may be displayed in bar graph, numeric or other format. Relative time, absolute time, various other information computed by the controller 160, including statistical information (e.g. average time per move) that intuitively represents timing information, may be displayed on the screen 152.

Some embodiments may include additional LCD or other displays in addition to the analog displays 104 and 106. Such additional displays may be configured locally with respect to the enclosure 102, or configured to display information at some remote distance from the controller. For example, in a match, the system may be configured to send information that may be displayed on a large screen, such as a scoreboard, for viewing by a large audience.

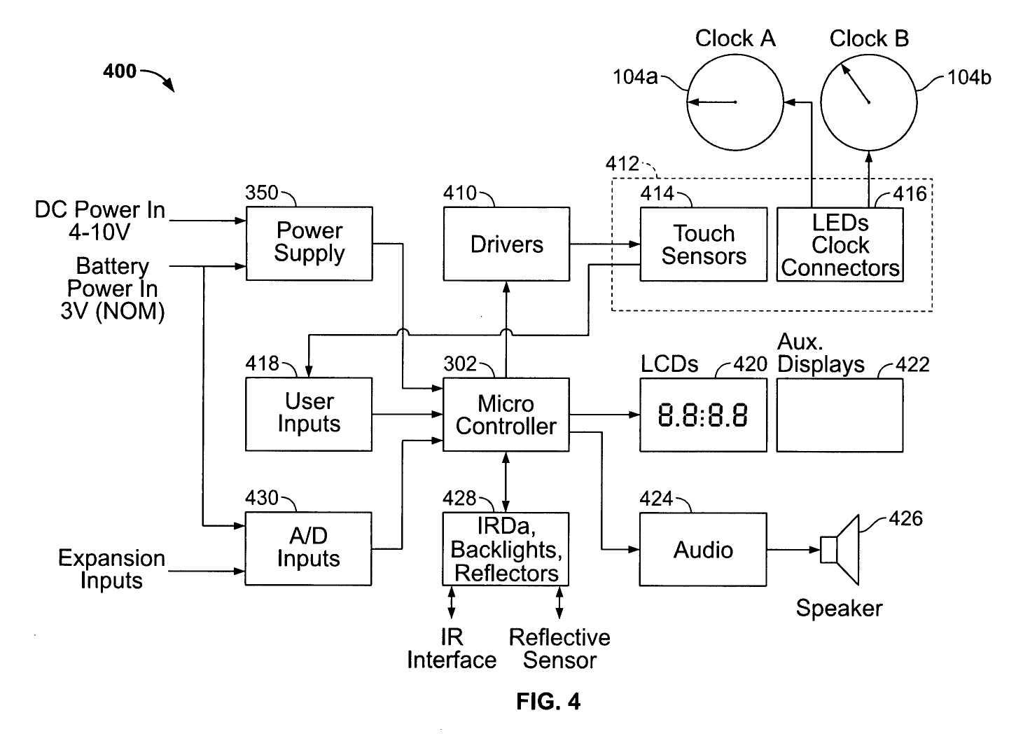

FIG. 3 illustrates an exemplary system architecture according to one embodiment of a PAT 300. Busses (data, address, memory, power, etc.) are not shown in detail in FIG. 3, and the connections between modules are meant to be merely representative. An application specific integrated circuit (ASIC) or field programmable gate array (FPGA) may alternatively replace one or more of the modules in FIG. 3. Some modules may be implemented using digital or analog circuits that may be discrete or integrated. Microprocessors or microcontrollers may be configured to execute sets of programmed instructions to perform tasks and functions as described herein.

In operation, a microcontroller 302 may execute software instructions to perform algorithms and tasks associated with managing the various functions of the PAT 300. As is conventional, the software instructions may initially be stored in non-volatile memory 304 such as read-only memory (ROM), flash memory, electronically programmable read-only memory (EPROM), electrically erasable programmable read-only memory (EEPROM) and the like. Non-volatile memory 304 may be updatable, such that software updates may be provided or downloaded to the PAT 300, for example by using a JTAG interface, a dedicated reprogram header and cable, or by replacing a socketable chip. Reprogramming the system 300 may be accomplished, for example, by wired or wireless communication over the Internet or a Bluetooth connection with provision of suitable transceivers and controllers.

As is conventional, the software instructions may be loaded from non-volatile memory 304 to a local memory (not shown), from which microcontroller 302 may access the instructions and execute them. The local memory may be static random access memory (RAM), non-volatile random access memory (NVRAM), dynamic RAM (DRAM) or the like. The memory 304 and the local memory may be incorporated within the microcontroller, or they may be separate. The controller 302 may include a real-time clock for time-keeping purposes. The controller 302 may monitor the various elements of the PAT to detect faults (e.g., low battery, malfunction, etc). The controller 302 may display the fault information on one or more of the displays, such as by flashing an LED, writing a description of the fault to an LCD, or communicating the fault information to an external device.

The controller 302 is coupled to clocks 306, 308, and more specifically, to the motors that move the hands 106a, 106b (see FIG. 1A). The controller 302 applies the appropriate signals to drive circuitry associated with clocks 306, 308 to cause the hands to advance or retreat as needed. During calibration, the hands may each be positioned automatically by the controller 302 operating the drive circuits, or by using mechanical or manual means.

The controller 302 is coupled to input interfaces 310, 312 that receive input commands from the users, such as players A and B, respectively. Each input interface 310, 312 each represent input switches (e.g., 112), rotary selectors (e.g. 108, 120), touch switches, and the like that may be available to each player. Users may use mechanical switches, traditional chess clock mechanical plungers with switches, Hall effect sensors, load or strain gauge sensors, reflective light techniques, or other passive or active touch sensing methods. In addition, user inputs may be received from wired or wireless remote controls. The controller 302 may monitor these inputs, for example, by polling, or by interrupt. In one embodiment, each player may have a numeric keypad for programming the rate of advance. By operating the input controls specific to each user, each user can program the corresponding time base and operate the corresponding portion of the PAT during operation.

The controller 302 is also coupled to a general input interface 314. The interface 314 represents all input controls that are not dedicated to a particular user. Such interface controls may include, for example, the operate button 116, and the port 118. The controller 302 may monitor these inputs, for example, by polling, or by interrupt, for example. The port 118 may provide wired connectivity to a network or other external device. The external device may be a client, a peer, or a server of the PAT 300. In some embodiments, the port 118 may send information to external devices under the control of controller 302.

The controller 302 is also coupled to an audio interface 316. The audio interface 316 may include an amplifier circuit that drives a sound-producing element, such as a speaker or buzzer. The sound producing element may either be incorporated within the PAT 300, or external to it. The speaker amplifier may be used to amplify sounds emitted during setup or operation. Optionally, sounds may be provided over the IR interface, optionally processed, then routed through the amplifier to the speaker. In some examples, the controller 302 may be programmed to configure the amplifier circuit to generate audio output at various settings of volume and equalization, for example. In some examples, the audio interface may be configured to provide music, tones, white noise, or synthesized or recorded voice output. For instance, the audio output may communicate timing information, for example, to the users. Furthermore, the audio interface 316 may be configured to receive audio input signals, such as from a microphone, for example. As can be appreciated, the PAT may be configured to respond to voice commands or other sound signals received through the audio interface 316. In one example, a player can complete a turn by saying a key word, such as “done,” instead of touching the switch. Board pieces may feature switches that when trigger the PAT switch by emitting sound or other signal when pieces are moved. Thus, the audio input can provide for hands-free operation of the PAT 300.

The controller 302 is also optionally coupled to an analog-to-digital converter (ADC) interface 318. The ADC may be used, for example, to control the charging of batteries. An ADC may also be used, in some embodiments, to measure the angle of rotation of the indicator, such as when a potentiometer is used to measure the angle.

The controller 302 is also optionally coupled to a reflective sensor 320. In one embodiment, the sensor 320 includes a light source and a photodetector that detects the reflection of the light from the light source. An LED (e.g., infrared) may be used to reflect light off the back side of the clock hand. Using reflective material, an optional lens and a photodetector, the clock hand position may be sensed to support automatic calibration. Furthermore, by sensing the proximity of the hand to the 12 o'clock position, for example, the PAT may be able to sense the approach of the end of a game. As such, when the sweep hand reaches end of total distance (indicating TT), the PAT may be configured to provide some additional signal (e.g., audible indicator, flashing light, or the like), or change operating mode in some manner. Likewise, an embodiment of the PAT may allow digitally programming of audio or visual warning signals to activate at any point of choice. Furthermore, the detected signal may be monitored to determine if there is a position error that may be corrected by an appropriate sequence of forward or backward drive signals. Alternatively, the position of a hand may be detected in various ways that have various advantages and trade-offs and are thus not necessarily equivalent. In some embodiments, for example, a conductor may close a “switch” as a hand approaches a certain position. In a different embodiment, a conventional mechanical clock “flag” may be employed, wherein a piece may be raised and then dropped by the passing of the sweep hand. In alternative embodiments, the sensor 320 may use other means, such as a photo-interrupter, a Hall effect sensor, or other sensor. Angular position of a hand may alternatively be continuously monitored using techniques involving, for example, a potentiometer (single turn or multi-turn), or an encoder (infinite rotation angle) that may be coupled to the shaft, for example.

The PAT 300 may also optionally include an infrared (IR) interface 322 for communicating with external devices. IR data may be received from one or multiple sources, and transmitted to multiple receivers for display or other purposes. Alternatively, the system 300 may include a telemetry module to facilitate wireless communication with external devices, including wireless control of the PAT 300, and wireless numeric and/or analog displays. PAT 300 may be reprogrammed using a personal computer, personal digital assistant (PDA), cell phone, or any other appropriate device.

The controller 302 is also coupled to a display. In some embodiments, each of displays 330, 332 allows information to be presented to two users under control of the controller 302. In particular, the displays allow each user to program a time base that sets the pace for the corresponding timing indicator. In one embodiment, displays 330, 332 includes a liquid crystal display (LCD) and associated drive circuitry. Displays 330, 332 may be backlit by backlights 336, 338. Under control of the controller 302, backlights 336, 338 may provide ease of readability in low lighting conditions, and may include sleep modes that dim or turn off the displays during periods of non-use. The LCD's may also be backlit with LEDs (e.g., white) to give better visibility and contrast in low lighting conditions. The backlights may also be used to illuminate the winner or loser display. In addition to displays 330, 332, the controller may also operate other auxiliary displays 334, as previously described with reference to the display 150 in FIG. 2B.

The PAT 300 is powered by electrical energy supplied by a power supply 350. The power supply 350 may receive an alternating current (AC) line power input signal, or it may operate from battery 352. The power supply 350 converts the input power to a regulated direct current (DC) signal suitable for powering the elements of the PAT 300. Optionally, the power supply 350 may include a battery charger for charging the battery 352 when operated from AC line power. Timers may incorporate other power sources in addition to, or instead of, wall or battery power, such as solar cells, to directly operate, or to recharge batteries.

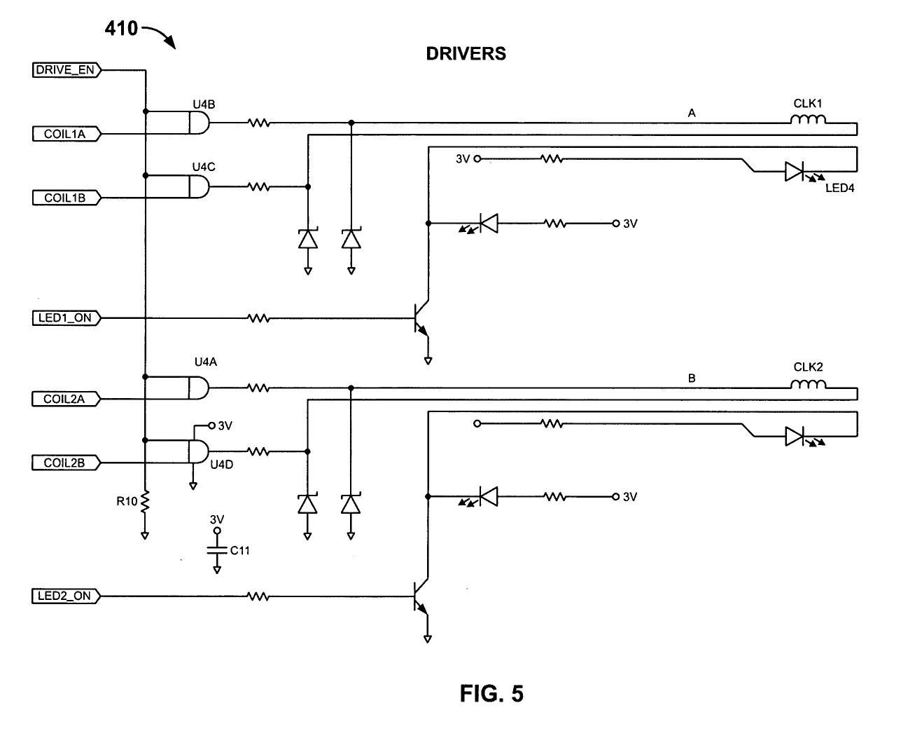

In FIG. 4, a functional block diagram of an exemplary PAT 400 is shown. Here, the microcontroller 302 is represented as being coupled to various circuits in the system 400. The controller 302 couples to the power supply 350. The power supply 350 may include power inputs as supplied from a DC wall source or a battery, and may provide voltage regulation and current limiting. An optional backup battery may also be included.

User input block 418 is coupled to the controller 302 and includes, in one embodiment, two rotary encoder inputs (rotary selectors 108a, 108b) and three user switches 112a, 112b, and 116. In one embodiment, a connector may be provided to allow the three switches to be moved to a printed circuit board (PCB) 412 and implemented as momentary or touch switches 414. A touch sensor block 414 may provide optional touch sensor inputs for the left and right player inputs.

An optional A/D Input block 430 provides optional analog-to-digital conversion and an expansion I/O connector for battery level monitoring and battery charge control.

The microcontroller block 302 may include any of the following capabilities and features: Flash program memory; RAM; processing unit; crystal time base; JTAG software development interface; digital inputs and outputs; and, on-chip peripherals, such as interrupt controller, timers, pulse width modulation controllers, and a serial port. Details about the operation of microcontroller 302 are described elsewhere herein.

An optional block 428 provides communication capabilities, for example, through the port 118 (FIG. 1B). Remote IR device(s) may provide wireless setup or runtime inputs, service an auxiliary display system, or provide a source for re-programming. Also represented in the block 428 are circuits for sensing the position of the analog hands. As described elsewhere herein, this may include an optional circuit for detecting light reflected off of a hand.

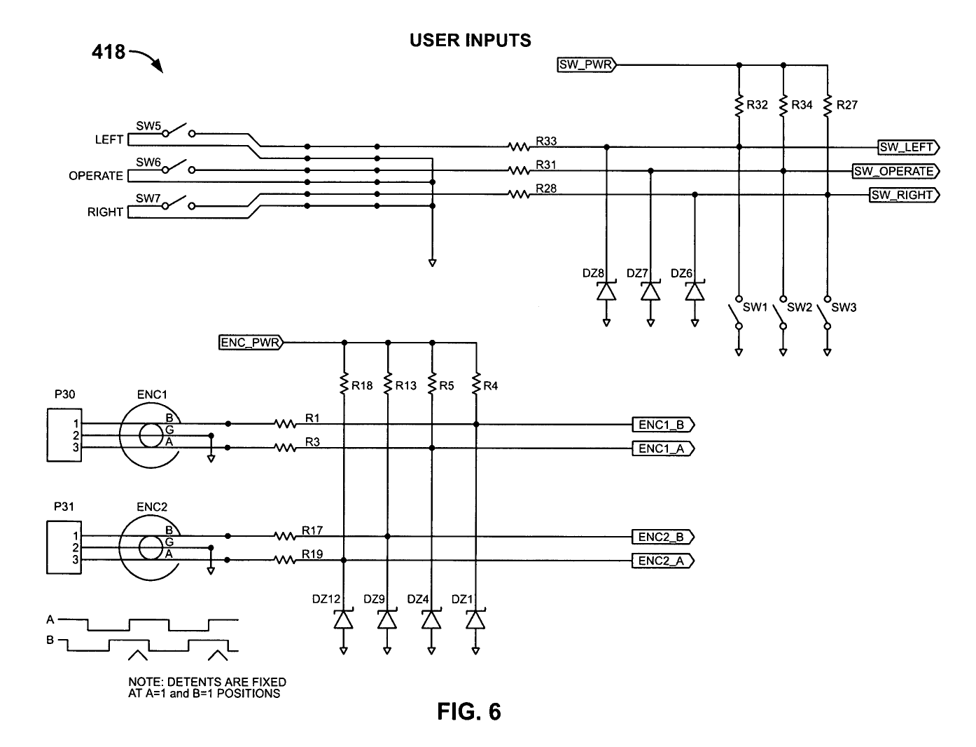

A drivers block 410 includes drivers for driving the coils that operate each of the hands 106. The drivers block 410 also includes circuits for controlling each player's LED. The driver circuits are controlled by the microcontroller 302, and are described in further detail with reference to FIG. 5.

The microcontroller may also control the operation of display blocks 420, 422. The display block 420 includes LCD displays, such as displays 110, 122 (see FIG. 1A-1B). The display block 420 may include an LCD controller which may be operatively coupled to the front and rear displays. In addition, auxiliary display block 422 may include one or more displays that may provide additional display capabilities using any suitable display technology, as described elsewhere herein.

An audio block 424 provides the capability for the microcontroller to produce audible signals to the users. The audible signals may include informational or entertaining chirp, beeps, tones, voice, music, and the like, to enhance the performance of the PAT. Furthermore, some embodiments may include the capability to receive audio input, such as voice commands as user input.

Corresponding to the drivers block 410, an exemplary schematic of a circuit for driving the analog clock coil is shown in FIG. 5. This circuit provides the drive signals to the analog displays when the overall drive enable (DRIVE_EN) signal is active (high). In one embodiment, the analog clock coil, motor, and gears may be provided by a conventional analog clock mechanism.

In this example, each analog clock coil is driven by a differential pair of AND gates. Specifically, AND gates U4B/U4C drive one coil, and AND gates U4A/U4D drive the other coil. No current is driven when both AND gates are at the same level. A current in one direction motivates the coil's round permanent magnet to spin 180 degrees inside its electromagnetic housing, and current driven the other direction makes the magnet spin in the same direction another 180 degrees. This spinning drives gears that drive the analog hand 106.

According to one embodiment, a total of 3600 pulses are needed to drive the analog display hand 106 around the clock display 104 one revolution. The coil drive is timed to give a sufficient pulse to make the round permanent magnet spin enough to get around. The permanent magnets are designed to have a spin direction preference, so they tend to spin in one preferred direction when pulsed. However, if the pulse is sufficiently short, the magnet does not spin far enough, and it rotates back to its original position. If a subsequent pulse is applied at the correct time and direction, taking advantage of the returning magnet's rotational inertia, the clock's permanent magnet can be made to rotate in its non-preferred direction. This is useful for setting the analog clocks readout hand 106 to the desired position, otherwise referred to in this document as “Clock Calibration.”

Clock movements for this embodiment are driven by a differential digital signal that drives an electromagnetic coil that in turn rotates a permanent magnet one-half revolution and turns the analog hand by 0.1 degrees. The differential digital drive provides current only to motivate the magnet to turn, then turns the current off. Subsequent clock movements require alternating the magnetic flux in the electromagnet (by alternating the coil's current direction).

Single clock drive pulses of approximately 10 mS will turn the magnetic rotor in its preferred direction for an overall forward (clockwise) analog movement. Narrower clock pulses that are approximately 6 msec in duration, and with optimized period, will cause the permanent magnet to rotate in the opposite direction, resulting in the analog hand moving counter-clockwise. Clock pulse trains may be optimized for forward and reverse operation to match the physical and magnetic properties of the rotating magnet system. Such optimization may include varying voltage levels, drive time, period between pulses, pulse width modulation drive, and changing these variables dynamically or “on the fly”.

In other embodiments, the drive for the analog clock may include a brushed DC motor. An optional position sensor may be used to provide closed loop rotational (or positional) control. The motor may utilize a reduction gear for finer movement resolution. In another embodiment, a brushless motor may also be used with appropriate drive electronics. A stepper motor may also be used, with or without position sensing, and with or without a reduction gear. Other motors or movements may be used, such as continuous-sweep or “slave” movements.

Corresponding to the user inputs block 418, an exemplary schematic of circuits for the user input switches and for the rotary selectors (encoders) 108, 120 are shown in FIG. 6. The existing switch inputs are assigned as Left Player Switch 112a, Right Player Switch 112b, and Operation Switch 116. In the schematic, different sets of switches (i.e., SW1-SW3 or SW4-SW6) may be optionally populated for different switch technologies or locations, for example. Onboard momentary switches, off board switches, or touch sensors may be connected. Current limiting resistors and diode clamps are connected to provide ESD protection. In one example, each player has a touch sensor, plus an “operate” button for control and system setup. A simple momentary switch alternative may be provided. The user may provide any mix of touch and momentary switches by simply populating the circuit portions desired. Each touch sensor is ESD protected. The touch sensors are set for up to 60 second touch sensing, but may be reconfigured for 10 second or an indefinite period.

With respect to the circuits for the rotary selectors, two rotary encoders may be installed on board, or off-board by way of the connectors P30 and P31 as shown in the schematic. According to this example, to sense the encoder positions, the ENC_PWR signal must be driven high. The encoders have mechanical switches that open and close in a four state “quadrature” operation. The encoders used have mechanical detents that position the rotating knob so that both internal switches are in the open state, thus using the least amount of power and providing logic 1's at the detent positions. The quadrature states give positional change and direction information so the software system can count up or down according to the two switch positions. Velocity and acceleration may also be sensed for non-linear counting or setup operations, as desired.

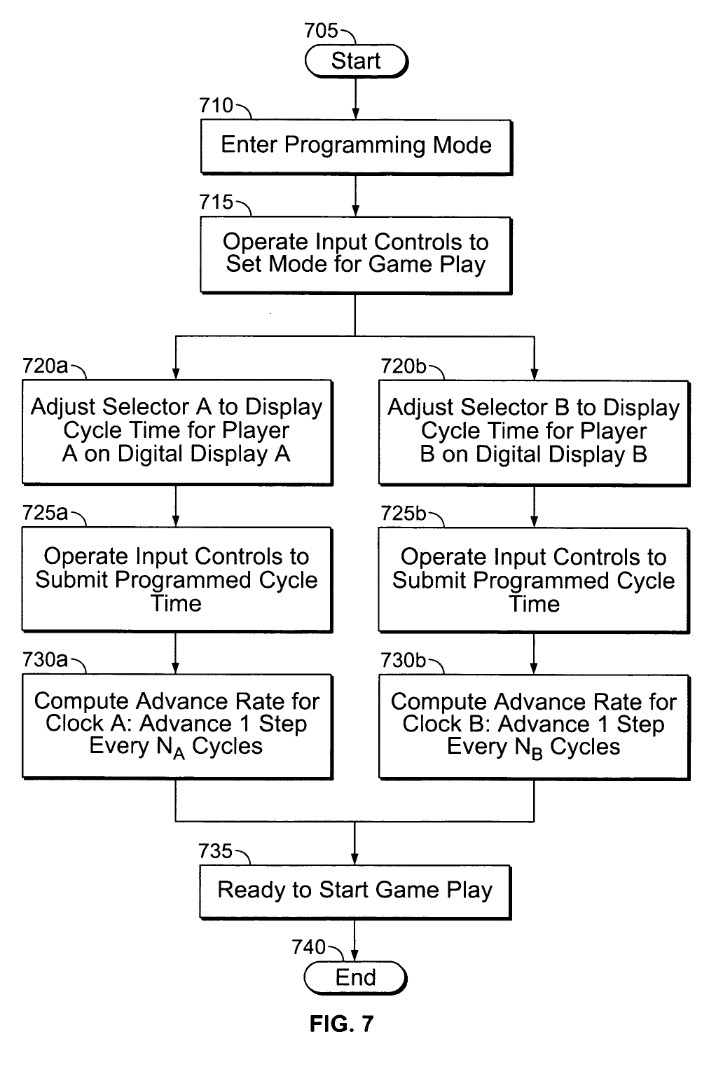

One method of programming the exemplary two-player PAT of FIG. 1A is illustrated in the flowchart of FIG. 7. Starting at step 705, the players (or users) may power up the system by pressing the operate button 116. In other embodiments, different control inputs may be used to perform similar functions. The system may automatically enter programming mode at step 710, wherein the displays 110, 122 may display a default value. At step 715, one of the players may operate the input controls according to a predetermined sequence in order to program the system to operate according to one of a variety of operating modes, such as those described elsewhere herein.

Next, the players may independently adjust their default time bases, which are displayed as numeric values on the displays 110, 122, by operating input controls at steps 720a, 720b. Specifically, each player may use the rotary selectors 108 or 120 to set the time base for the corresponding analog display 106. In addition, each player may have an opportunity to calibrate the starting/ending position for their indicator. When ready, each player may lock in the selected time base and calibration at steps 725a, 725b by operating the input controls (e.g., switches 112, 116) according to a predefined sequence to submit these settings to the system controller.

At steps 730a, 730b, the system controller may process the selected time bases by computing the advance rate for each clock, i.e. for each indicator 106. The advance rate for each clock may correspond, for example, to advancing the indicator 1 incremental step each time N cycles have passed. Each cycle may be based on various mechanisms such as, for example, a software loop counter, an internal hardware timer, or a real time clock that the controller monitors. The advance rate may be a function of, for example, the total time (TT), total angle of rotation for a complete sweep, and any non-linearities (e.g., variable rate schedules, logarithmic rates) associated with the programmed mode of operation set in step 715.

At step 735, the system has been programmed to operate in a desired mode and at desired advance rates. As such, the system is ready to be operated by starting game play. The system exits programming mode at step 740.

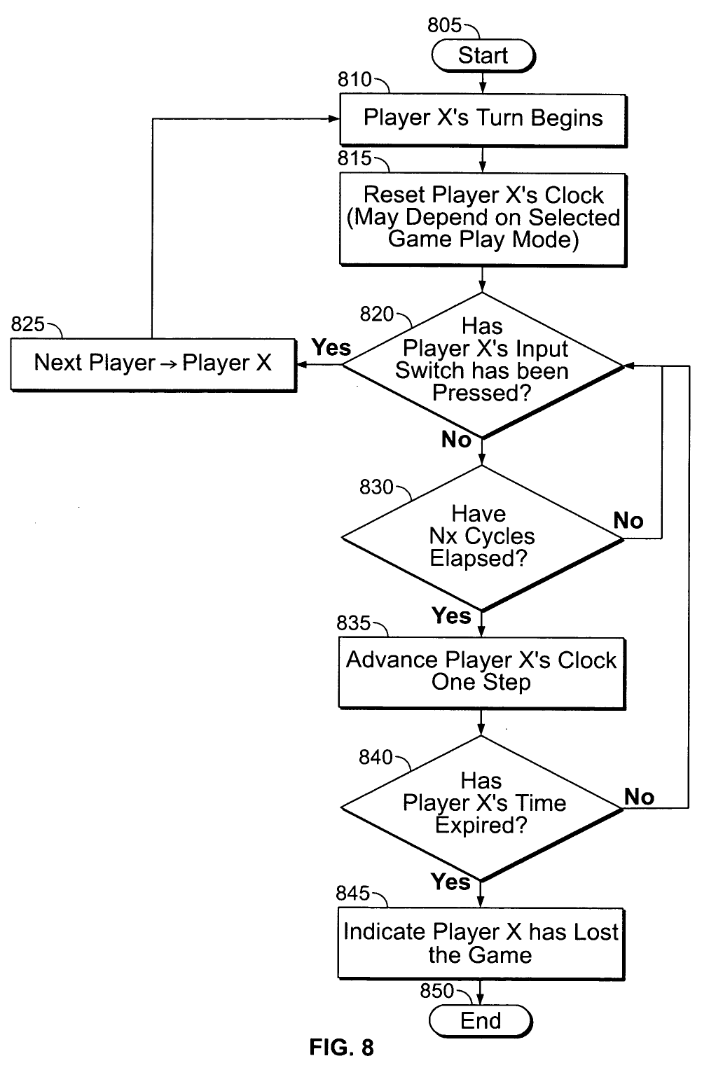

One method of operating the exemplary two-player PAT of FIG. 1A is illustrated in the flowchart of FIG. 8. Starting at step 805, one player (referred to herein as player X), begins a turn at step 810. At step 815, the system player X's clock is reset to its programmed starting position. Typically, step 815 is performed only once per game. In some embodiments, step 815 may be performed at other times, such as prior to the start of game play.

If player X's input switch (e.g., switch 112) has been pressed at step 820, then player X's turn ends, and the next player becomes the active player X at step 825. The new player X's turn begins at step 810.

However, if player X's input switch has not been pressed, then the system (controller) determines whether Nx cycles have elapsed at step 830. In this example, Nx represents the number of cycles computed in step 730 for the currently active player. If the required number of cycles have not elapsed, then control flow loops back to step 820. However, if the required number of cycles, Nx, have elapsed, then player X's clock (indicator 106) is advanced one step, or increment, at step 835. In addition, the count of elapsed cycles may be reset.

If player X's indicator 106 has advanced to its end position, which (in some modes of play) means that player X's time has expired at step 840, then the system indicates that player X has lost the game at step 845, and the game ends at step 850. However, if player X's time has not elapsed, then control flow reverts back to step 820.

In various embodiments, a PAT may include one or more analog rotary display(s) or other kinds of displays, with optional complementary numeric display and/or linear display(s). Such displays may be configured, by programming or other means, to provide intuitive measures of each player's proportional elapsed and remaining time. Accordingly, such displays may provide quick or intuitive comparison of players' times, especially when both analog hands sweep the same total angle.

In some embodiments, the rotary displays may be programmed for single or multiple hand sweeps, and user(s) may calibrate the start/end position anywhere on the 360 degree analog clock. Analog displays may be set, controlled, and monitored numerically (e.g. with digital numeric displays). In addition, rotary and/or linear displays may be programmed to operate forward and backward (or up and down, etc.), or back and forth (e.g., reciprocating movement).

Some examples may include non-moving touch-sensitive switches on the user interface, and optional lighting (including backlighting) for any or all displays. Programming and operation methods may use rotary encoder(s) as user control(s).

In various embodiments, the PATs may be powered by AC or DC power. As such, wall power and/or battery operation may be supported. Furthermore, some examples may use an optional smart rechargeable battery. In some examples, a charging controller may be built into the PAT.

Operation of various embodiments may involve variable speeds or rates of rotation, and may involve various display settings. One example may include linear time for single revolution operation, or linear time for multiple revolution play. A second example includes multiple speeds for multiple revolution play. For instance, a final minute may receive one extra full revolution. A third example is non-linear time for single revolution operation. This may be used to achieve better end-game time resolution, for instance, by moving the hand slowly at the start of the game, and faster at the end. A fourth example is delayed operation, in which each user receives a predetermined grace period of time at the start of each use. For instance, a chess player's clock may have a one-second delay at the beginning of each move.

Still other examples are possible. A fifth example is reverse operation, in which each user receives a predetermined time award at the start of each use. For instance, a chess player's clock adds one second at the beginning of each move. A sixth example relates to the possibility of single display operation. For instance, the display indicator may advance in one direction for one player, but advance in an opposite direction for the opposing player. In this mode of operation, time may expire if the display moves the entire preset distance (e.g., one full revolution in either direction).

The PAT may include at least one processing unit capable of performing functions to support various modes of operation. A processing unit may be implemented in hardware (digital or analog or mixed), or in some combination of hardware and software. Herein, the processing unit is generally considered to reside at least in part on the controller; however, that is merely for purposes of describing illustrative embodiments. However, other embodiments are possible. For example, all higher level processing may be performed remotely on a central server. In such an embodiment, the local PAT may receive commands and display information as a client of the server. Accordingly, the client (local PAT) may send user input information to the server, and the server may send signals to the clients to advance the analog displays and to display information for other audio and visual display elements.

In one embodiment, the user may be able to program favorite game settings, for example, into non-volatile memory. As such, the user may recall the settings quickly during subsequent use of the system.

A number of embodiments of the invention have been described. Nevertheless, it will be understood that various modifications may be made without departing from the spirit and scope of the invention. For example, various visual indicators, such as lamps, LEDs, flashers, or other visual indication means may be used for display to the user. In addition, various types of input controls (e.g., knobs, dials, buttons, motion sensors, proximity detectors, keypads, joysticks, touch screens, key boards, mouse pointing device, and the like) may be substituted for user inputs such as switches 112, 116 and rotary selectors 108, 120. As a further example, the system may include an audio/voice output indication of time, including proportional time, time differential, critical times (e.g. “1 minute remaining”), count down, and similar information that may be of interest to a listener. In other examples, the timer may activate other signals that indicate timing information. Examples of this activation may include vibrating (i.e., as in a pager or cell phone), activating a motor to cause motion, flashing colored lights in a programmed manner, or other similar techniques to gain the attention of observers, or to indicate timing information. In another embodiment, the system may provide an encoded signal that may be received and decoded by an electronic receiver. The decoded signal may be used to trigger a remote action. For example, the decoded signal may be used, in the examination context, to flash lights in the examination room, along with playing an audio recording of instructions to stop writing. In the recreation context, the system may be used send a signal to initiate the release of a support member such that a losing player is dropped into a dunk tank.

A PAT may be used in various other applications in which a sense of elapsed and remaining time relative to a predetermined complete period, or in comparison to others' elapsed and remaining time, or that of a preset or recorded performance (such as a course record), is desirable. A PAT may include one or more analog indicators controlled by one or more programmable sweep controllers. In most embodiments, the controllers are programmed to operate the multiple analog indicators independently. During operation, each analog indicator, when running, may advance according to a rate or function of time so it covers a known sweep distance (often one full revolution or linear course) over the course of the programmed completion time(s). Upon viewing the analog display, an observer may in certain embodiments quickly ascertain proportional, relative, elapsed and remaining time information from the position, angle, or state of each indicator.

### Connecting Multiple PAT Devices

A telephone link may be used to connect two or more PAT units so players at different locations can play remotely and still see the relative analog indicators on their PAT devices. One embodiment involves the production of a DTMF tone or modem signal that is activated by the controls of each PAT device. The other PAT device receives and interprets the DTMF tone or modem signal and allow players to utilize separate PAT units remotely and play in real time over the telephone. The DTMF or modem signals serve as the control and configuration communication means between the multiple PAT units.

Two or more PAT devices may be linked as a network of “Distributed Analog Timers” (DATs). A DAT system may involve the Internet an/or other network or communication means as a medium to distribute the controls and/or relative display positions to multiple PAT systems. The inter-connect medium may be wired such as Ethernet, USB, serial, or analog control wires, or may also utilize wireless medium, such as WiFi (wireless Ethernet), USB OTG (USB on the go), BlueTooth and IrDA (infrared link). Wired and wireless mediums may both be used too. Protocols may include TCP/IP, UDP, pager protocols, Packet Radio, or other means to reliably distribute information from one unit to another.

In a DAT system, participating PAT devices may include a transmitter and a receiver to communicate each user's switch controls, configuration and optionally timer data to the other PAT devices. The PAT devices may communicate with a master controller. This optional master controller may be another PAT, or may simply be a software application running locally or remotely (e.g. on the internet). Transmitted user controls, configuration and data may control the PAT's indicator(s) on the other system(s).

Additionally, display-only PAT devices may also be used as additional local or remote display systems. These display-only PAT units may only need receivers since they won't transmit controls or configuration to the other units.

For remote play notification, phone or pager/beeper devices may be used to notify a player of their turn and may also relay relative timer condition. Play notification may be received in the form of text message, vibration, sound, light, analog display or other form. Control responses may also be implemented on the remote device to convey the player's control back to one or more PAT units and an optional master controller unit.

PAT Indicators

A PAT device may have MULTIPLE indicators, including any combination of analog and numeric indicators, within a single multi-function display. The indicators may use separate axes or a common axis. For instance, each of the two displays of a chess clock may feature a sweep hand with a numeric indicator marking time, and/or number of moves, etc., mounted within the dial.

A game timer embodiment may feature numerous sweep hands, distinguished by colors, each corresponding to a different player in a multi-player game, where each hand can be activated and stopped at the beginning and end of its corresponding player's turn.

A PAT device may feature a single indicator that represents multiple players, such as an indicator that travels or rotates in a different direction for each player. For example, a two-person or two-team game PAT may feature a sweep hand or linear indicator that moves clockwise or to the right for one person/team, and counterclockwise or to the left for the opposition. The user control switch changes the indicator's direction at the start of each player's/team's move. A loss by expiration of time is signaled by the indicator's completion of sweep or course, much like the flag on a rope crossing a line in tug-of-war, or by a loss on the board, for example “checkmate”. One embodiment may feature a disk of neutral color, with clockwise and counter-clockwise sweeps of different colors, each representing a player, which fill in the disk face as they progress. The player loses when the entire 360 degrees of the disk has filled with his color.

### Additional Embodiments

The PAT may be implemented in hardware and/or software systems for standalone embodiments. Networked distributed embodiments may be implemented using fixed or mobile PAT units. The following descriptions and applications of embodiments apply to hardware and/or software implementations. The user interface may range from traditional buttons and analog dial indicator(s) to possible networked devices and optional remote controls. In addition, the described indicator(s) may be displayed on a monitor or scoreboard or projected onto a surface.

A chess clock is one embodiment of the PAT concept. Additionally, the PAT may provide a timing reference for other contests and games, such as Scrabble, Pictionary, charades, Isketch, crosswords, Trivial Pursuit, and other games and recreational activities requiring or enhanced by time limits, sense of pace, or sense of relative time.

One embodiment may include a method of remotely signaling a player when it is his or her turn. For example, the PAT may contain a transmitter activated by a user switch that sends a signal to one or more PAT receivers using wired or wireless techniques and involving communication from one stationary or portable system to one or more system(s). This transmitted signal would influence the indicator(s) on the other system(s).

The PAT system may implement one or more analog timers on a LCD or similar display. So, a complete PAT system may be implemented on a PDA (personal digital assistant) or a laptop/notebook computer, a Blackberry handheld device, or other system which is programmable and provides a user interface which can implement an analog style display and accept user inputs.

PAT(s) may be installed on exercise machines, lecterns, podia, pulpits, rostra, desks, walls and other equipment and facilities servicing sessions where a sense of pace or RELATIVE elapsed and remaining time may be advantageous, such as examinations, debates, lectures, interviews, structured discussions, exercise and training sessions. A PAT employed in this service, and in others described in this document, may be displayed in conjunction with traditional clocks to give the user both an indication of fixed and relative time.

PAT(s) may be incorporated into equipment or mounted on displays where it is advantageous for the Timer to be set to complete its Total Time (TT). This TT time may be tied to prior-known durations, such as oxygen expenditure in diving tanks, the duration of military and other missions that must be completed within a time limit, set-time periods for classes, counseling, physical or other therapy, consultations, massage, meditation, work, recreation, breaks, and other activities of a fixed Total Time. Again, a PAT employed in this service may be displayed in conjunction with traditional clocks to give the user both an indication of fixed and relative time.

PAT(s) may be implemented on equipment or mounted on display where medical, dental, and cosmetics procedures involve time limits, such as the application of hair or skin products, dryers, heat, teeth whiteners, bonding agents, ultra violet light, radiation, infusions, medicines and chemicals. This can be useful not only for the administrator, but also the patient, who may wish to have a sense of where he is in relation to the entire procedure time.

PAT(s) may be implemented on equipment or mounted on display, may be carried or worn (as a wristwatch, cell phone, on a belt, or carrying case) by coaches, participants, spectators, referees, or displayed on film, public boards and screens, television broadcast, and similar venues for sports and other activities to set or display a pace (lower than, the same as, or better than) an established TT, or to compare a participant's speed relative to a desired speed, such as a record, an optimal training rate, a minimal speed required to gain a place in subsequent heats, avoid elimination, and so on, or speeds set by earlier competitors in the same meet or other events.

One application of this may be the projection or display of a phantom moving object, such as an animated runner or cyclist, into a television broadcast of a race, where the phantom represents, as a constant speed calculated to finish the course at a pre-determined time, the time to beat, such as a course record. Though the actual competitors will likely not maintain constant speed, nevertheless, the PAT may provide a dramatic and useful comparison of pace.

PAT(s) may be incorporated into equipment or mounted on display in a household to monitor tasks such as cooking, washing, drying, oven cleaning, and other activities involving timing or time limits. Such PAT devices may be stand-alone or installed on ovens, microwaves, washers and dryers, and other apparatus.

PAT(s) may be incorporated into equipment or mounted on flight display to track the flight pace in relation to the ETA, and alerting the pilot to a potential arrival time fifteen minutes beyond the submitted flight plan ETA, which would require notification of the tower. The PAT may take the form of a single sweep, or image animation, such as a moving point traversing a map of the actual flight path.

PAT(s) may be implemented as a feature on one or more wristwatches, portable phones, GPS units, PDAs or other computing devices.

PAT(s) may be implemented on equipment or mounted on displays where it is advantageous for the Timer to be set to complete its TT as a relative-time countdown to a prior-known or planned event, such as that of an upcoming eclipse, show times, departures & arrivals, openings & closures, or to the start or end of any event or activity, where a sense of precision, suspense, pace, relative time, and so on, is desirable. Typically, a PAT employed in such service would be set in activation at a moment meaningful in relation to the awaited event. One example may be the beginning of a sale in relation to when the sale ends, wherein the public can SEE that it has, for instance, less than half of the total sale period remaining, thereby instilling a sense of drama and urgency to the event. The relative-time countdown to the opening of a gallery may begin with the public announcement of a show; the relative-time countdown to the birth of a rare zoo animal may begin with the determined moment of conception and be programmed to end at the expected time of birth; and so on.

1. An analog display system, comprising:
a first analog display element having an indicator that sweeps at a first sweep rate;
means to receive a user input associated with a desired sweep rate or an elapsed time; and
a display driver to i) receive the user input, ii) set the first sweep rate according to the user input, and iii) drive the first analog display at the first rate.

2. The system of claim 1, further comprising a second analog display element having an indicator that sweeps at a second sweep rate.

3. The system of claim 2, wherein the display driver further sets the second sweep rate according to user input and drives the second analog display at the second sweep rate.

4. The system of claim 1, wherein the receiving means comprises a manual selector.

5. The system of claim 4, wherein the selector comprises a numeric display and one or more switches to select a value corresponding to a desired sweep rate or a time period.

6. The system of claim 5, wherein a number corresponding to a desired sweep rate or a desired time period is displayed on the numeric display.

7. The system of claim 1, further comprising a first switch to selectively stop and start the first analog display element.

8. The system of claim 1, wherein the user input is a time period corresponding to one revolution of the indicator.

9. The system of claim 1, wherein the first analog display element includes a dial and the indicator comprises a hand.

10. The system of claim 1, wherein the first analog display element includes a plurality of hands and wherein the display driver sets the sweep rates for the plurality of hands.

11. The system of claim 1, wherein the first sweep rate varies as the indicator sweeps.

12. The system of claim 1, wherein the user input relates at least to a desired elapsed time.

13. The system of claim 1, wherein the user input relates to a sweep direction and the display driver further sets the sweep direction based on the user input.

14. The system of claim 2, further comprising a paging device to alert the user when one of the first and second analog display devices are stopped.

15. The system of claim 14, wherein the paging device communicates over a wireless link to a receiver proximate the user.

16. The system of claim 14, wherein the receiver is a portable computer device.

17. The system of claim 1, further comprising a transceiver to communicate with a remote device.

18. The system of claim 17, wherein the receiving means comprises the remote device.

19. The system of claim 17, wherein the transceiver is wirelessly coupled to a network adapter.
